(19) United States
(12) Patent Application Publication
(10) Pub. No.: US 2025/0231494 A1
(43) Pub. Date: Jul. 17, 2025

(54) COMPREHENSIVE INSPECTION EQUIPMENT FOR EUV EXPOSURE PROCESS

(71) Applicant: IUCF-HYU (INDUSTRY-UNIVERSITY COOPERATION FOUNDATION HANYANG UNIVERSITY), Seoul (KR)

(72) Inventors: Jinho AHN, Seoul (KR); Dong Gi LEE, Seoul (KR); Young Woong KIM, Seoul (KR); Seungchan MOON, Seoul (KR); Jin Hyuk CHOI, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/853,617

(22) PCT Filed: Apr. 7, 2023
(86) PCT No.: PCT/KR2023/004718

§ 371 Date: Oct. 2, 2024

(30) Foreign Application Priority Data
Apr. 7, 2022 (KR) 10-2022-0043229

(51) Int. Cl. G03F 7/00; G03F 1/62; G03F 1/84

(52) U.S. Cl. CPC G03F 7/70608; G03F 1/62; G03F 1/84; G03F 7/7055; G03F 7/70666

(57) ABSTRACT

A comprehensive inspection device for an EUV exposure process includes: a light generation unit configured to generate EUV light; a splitter configured to split the EUV light into first EUV light and second EUV light; an optical characteristic evaluation unit configured to detect reflectance and transmittance of the pellicle and reflectance of the object by measuring an intensity of the first EUV light, which has been transmitted through the pellicle, reflected from an object, and re-transmitted through the pellicle, and an intensity of the first EUV light, which has been directly reflected from the object without the pellicle; and an imaging inspection unit configured to inspect imaging performance of a mask by focusing the second EUV light, which has been reflected and diffracted from the mask, through an objective lens, and then collecting the focused second EUV light to obtain an aerial region image.

### TECHNICAL FIELD

The present invention relates to a comprehensive inspection device for an EUV exposure process, and more specifically, to a comprehensive inspection device for an EUV exposure process, which may inspect optical characteristics of a pellicle and a mask for the EUV exposure process and imaging performance of the mask.

### BACKGROUND ART

In order to improve yield and productivity of an EUV exposure process, it is required to develop a pellicle that prevents contamination of a mask by preventing inflow of contaminants generated during the process. EUV light having a wavelength of 13.5 nm used in the EUV exposure process has a reflective optical system structure due to characteristics of the EUV light that is absorbed by most materials. Accordingly, when the pellicle is applied, the EUV light passes through the pellicle twice, and optical characteristics such as high EUV light transmittance and low EUV light reflectivity of the pellicle are required to suppress a decrease in productivity and a change in mask imaging performance due to the pellicle.

Since a pattern of the mask is repeatedly transferred to a wafer during the EUV exposure process, the introduction of a device capable previously of verifying defects and contamination of the mask may increase the yield of the process. When defects and contamination of the mask are confirmed during the EUV exposure process, it is possible to lower semiconductor manufacturing costs by applying the repaired mask to a mass production process through a process of correcting pattern defects or cleaning contaminants rather than remanufacturing the mask. There is a method of confirming whether the correction is successful through SEM review after direct exposure to the wafer using an exposure machine, even if the mask correction and cleaning processes are performed. However, since it takes a lot of cost and a long verification period, it is necessary to verify in advance an effect of mask defects on the wafer through measurement of an EUV mask aerial image using a microscope capable of depicting the optical system of the EUV exposure machine. Moreover, the EUV mask may evaluate the presence or absence of surface defects using an existing deep ultraviolet (DUV) or E-beam, but phase defects occurring inside a multilayer thin film may be accurately measured only through inspection using EUV light, which is referred to as EUV actinic inspection technology.

A conventional pellicle and mask inspection technology for an EUV exposure process have not yet been established, and clear technology and devices have not been proposed. As research on a pellicle for the EUV exposure process is being conducted worldwide, various research and development are also underway on devices for inspecting the pellicle. There is no established criterion, but in principle, inspection of a pellicle for an EUV exposure process is possible if it includes a detection system capable of measuring the intensity of EUV light having a wavelength of 13.5 nm and a light source passing through the pellicle. Among the technologies, the most related technologies pellicle inspection using a mass-production type exposure machine and pellicle inspection using a device designed with a transmissive structure.

As a conventional mask imaging performance inspection technology, there is a technology using the same optical system as the EUV exposure machine using a multilayer thin film mirror, and there is a method using a coherence diffraction imaging (CDI) technology that does not use an objective lens. The CDI is a technology that detects the intensity of a light source diffracted from the mask and restores a mask aerial image through a phase restoration algorithm. The most relevant technology is a technology of measuring a mask aerial image by blocking wavelengths other than an EUV region by using an FZP lens and an order sorting aperture (OSA) as illumination systems and focusing EUV light on the mask.

The inspection of the pellicle and the mask through the EUV exposure machine involves great risk because it may cause serious contamination in the exposure machine due to contaminants or destruction of a pellicle thin film. In a situation where the price of the exposure machine is about KRW 150 billion, it is inefficient equipment operation to take the risk and use the exposure machine as pellicle inspection equipment. The pellicle inspection device for an EUV exposure process designed with a transmissive structure may inspect transmittance and defects by comparing intensities of EUV light before/after transmission through the pellicle, but unlike an extreme ultraviolet exposure machine in which EUV light is transmitted through the pellicle twice due to the reflective optical system structure, the pellicle inspection device may measure only one transmittance due to a simple optical system structure, and may not evaluate optical characteristics of a mask material. Therefore, since the pellicle inspection device may be utilized only for measuring the simple transmittance of the pellicle, it may be limitedly used in the research and development of the pellicle for an extreme ultraviolet exposure process.

In the conventional FZP mask inspection studies, the pellicle inspection device may focus EUV light using the principle of diffraction, and may block a wavelength other than EUV light through the OSA. However, the pellicle inspection device is used as an illumination system and is not used as an objective lens. When the FZP lens is used as an objective lens, an image may be formed by collecting mask diffraction light. However, in order to focus very short EUV light of 13.5 nm without aberration, ultra-precision alignment for satisfying an inclination of 0.03° or greater and a very short depth of focus of 0.36 um is required, and it is difficult to precisely align the FZP lens due to optical characteristics of EUV light that is easily absorbed in all materials. Due to the above problem, although the structure of the optical system capable of evaluating the optical characteristics of the pellicle and the mask material is simple, there are no mask imaging performance inspection technology using the FZP lens and a conventional technology of simultaneously performing the pellicle and mask inspection.

### DISCLOSURE

### Technical Problem

One technical problem to be solved by the present invention is to provide a comprehensive inspection device for an EUV exposure process, which may perform both optical characteristic inspection for a pellicle and a mask for the EUV exposure process and mask imaging performance inspection through one inspection device.

Another technical problem to be solved by the present invention is to provide a comprehensive inspection device for an EUV exposure process with minimized time and costs required for inspection.

Still another technical problem to be solved by the present invention is to provide a comprehensive inspection device for an EUV exposure process, which may easily measure a reflectance for a pellicle and a mask through a composition of an environment such as an actual exposure machine.

Still another technical problem to be solved by the present invention is to provide a comprehensive inspection device for an EUV exposure process with improved accuracy of optical characteristic inspection for a pellicle and a mask. Still another technical problem to be solved by the present invention is to provide a comprehensive inspection device for an EUV exposure process with improved image performance inspection for a mask.

The technical problems to be solved by the present invention are not limited to those described above.

### Technical Solution

In order to solve the above-described technical problems, the present invention provides a comprehensive inspection device for an EUV exposure process.

According to one embodiment, the comprehensive inspection device for an EUV exposure process may include: a light generation unit configured to generate EUV light; a splitter configured to split the EUV light into first EUV light and second EUV light by receiving the EUV light from the light generation unit; an optical characteristic evaluation unit configured to detect reflectance and transmittance of the pellicle and reflectance of the object by measuring an intensity of the first EUV light, which has been transmitted through the pellicle, reflected from an object, and re-transmitted through the pellicle, and an intensity of the first EUV light, which has been directly reflected from the object without the pellicle; and an imaging inspection unit configured to inspect imaging performance of a mask by focusing the second EUV light, which has been reflected and diffracted from the mask, through an objective lens, and collecting the focused second EUV light to obtain an aerial image.

According to one embodiment, the object may include a first sample including a multilayer thin film mirror, and the optical characteristic evaluation unit may detect the transmittance of the pellicle by measuring an intensity of the first EUV light, which has been transmitted through the pellicle, reflected from the first sample, and re-transmitted through the pellicle, and an intensity of the first EUV light, which has been directly reflected from the first sample without the pellicle.

According to one embodiment, the object may further include a second sample including a material for absorbing EUV, and the optical characteristic evaluation unit may detect reflectance of the pellicle by measuring an intensity of the first EUV light, which has been transmitted through the pellicle, reflected from the second sample, and re-transmitted through the pellicle, and an intensity of the first EUV light, which has been directly reflected from the first sample without the pellicle.

According to one embodiment, the object may further include a third sample including a material used in an EVU process, and the optical characteristic evaluation unit may detect reflectance of the third sample by measuring an intensity of the first EUV light, which has been directly reflected from the first sample without the pellicle, and an intensity of the first EUV light, which has been directly reflected from the third sample without the pellicle.

According to one embodiment, the imaging inspection unit may include: a distance sensor configured to sense a distance between the objective lens and the mask; a control unit configured to confirm a tilt of the objective lens by using the distance measured through the distance sensor; and a tilting module configured to control a position of the objective lens, and the tilting module may control the position of the objective lens such that 0th-order diffraction light among diffraction light of the second EUV light, which has been diffracted from the mask, passes through a central portion of the objective lens.

According to one embodiment, the imaging inspection unit may further include: a first mirror configured to focus the second EUV light provided by the splitter, and a second mirror configured to change a path of the second EUV light such that the second EUV light focused through the first mirror is irradiated to the objective lens.

According to one embodiment, the splitter may reflect a part of the EUV light provided by the light generation unit and transmit a remaining part of the EUV light, and the EUV light reflected by the splitter may be defined as the first EUV light, and the EUV light transmitted through the splitter may be defined as the second EUV light.

In order to solve the above-described technical problems, the present invention provides an optical characteristic inspection device for an EUV exposure process.

According to one embodiment, the optical characteristic inspection device for an EUV exposure process may include: a light source configured to provide EUV light; an object which includes a first sample including a multilayer thin film mirror, a second sample including a material for absorbing EUV, and a third sample including a material used in an EUV process, and irradiated with the EUV light provided by the light source; a pellicle spaced apart from the object face the object; a detector configured to measure an intensity of the EUV light, which has been transmitted through the pellicle, reflected from the object, and re-transmitted through the pellicle, and an intensity of the EUV light, which has been directly reflected from the object without the pellicle; and a calculation unit configured to detect reflectance and transmittance of the pellicle and reflectance of the object through the intensity of the EUV light detected through the detector.

According to one embodiment, the calculation unit may detect the transmittance of the pellicle through the following <Equation 1>.

$${T}_{P} = \sqrt{\frac{B}{A}} \qquad 〈 Equation 1 〉$$

(T_{P}: Transmittance of pellicle, A: Intensity of the EUV light directly which has been reflected from the first sample without the pellicle, B: Intensity of the EUV light which has been transmitted through the pellicle, reflected from the first sample, and re-transmitted through the pellicle)

According to one embodiment, the calculation unit may detect the reflectance of the pellicle through the following <Equation 2>.

$${R}_{P} = \sqrt{\frac{C}{A}} \cdot X \qquad 〈 Equation 2 〉$$

(R_{P}: Reflectance of pellicle, A: Intensity of the EUV light which has been directly reflected from the first sample without the pellicle, C: Intensity of the EUV light which has been transmitted through the pellicle, reflected from the second sample, and re-transmitted through the pellicle, X: Reflectance of the first sample)

According to one embodiment, the calculation unit may detect the reflectance of the third sample through the following <Equation 3>.

$${R}_{S} = \sqrt{\frac{D}{A}} \cdot X \qquad 〈 Equation 3 〉$$

(R_{S}: Reflectance of third sample. A: Intensity of the EUV light which has been directly reflected from the first sample without the pellicle, D: Intensity of the EUV light which has been directly reflected from the third sample without the pellicle, X: Reflectance of the first sample)

In order to solve the above-described technical problems, the present invention provides an objective lens tilting device.

According to one embodiment, the objective lens tilting module may include: first to third driving modules spaced apart from each other along a circumferential direction; a first plate having a circle plate shape, which is coupled to one end of each of the first to third driving modules to support the first to third driving modules; a second plate having a circle plate shape, which is coupled to the other end of each of the first to third driving modules so that movement thereof is changed by the first to third driving module; and a lens holder coupled to the second plate so that movement thereof is changed by the second plate, and having an objected lens mounted thereon, in which the second plate and the lens holder may be rotated along a circumferential direction of the second plate by the first to third driving modules, or may be changed in inclination, and a position of the objective lens mounted on the lens holder may be changed due to the change in movement of the lens holder so that alignment of EUV light focused through the objective lens is controlled.

According to one embodiment, each of the first to third finger modules may include: a lower slide configured to linearly reciprocate in a first direction parallel to an upper surface of the first plate; a middle slide disposed on the lower slide, and configured to linearly reciprocate in a second direction parallel to the upper surface of the first plate and perpendicular to the first direction; and an upper slide disposed on the middle slide, and configured to linearly reciprocate in a fourth direction inclined with respect to a third direction perpendicular to the first direction and the second direction.

According to one embodiment, the objective lens tilting device may further include: a distance sensor configured to sense a distance between the objective lens and a mask for reflecting the EUV light, in which an inclination of the objective lens may be confirmed using the distance measured through the distance sensor, and the first to third driving modules may be controlled to allow 0th-order diffraction light among diffraction light of the EUV light, which has been diffracted from the mask, to pass through a central portion of the objective lens.

### Advantageous Effects

According to the embodiment of the present invention, the comprehensive inspection device for an EUV exposure process may perform both optical characteristic inspection for a pellicle and a mask for the EUV exposure process and mask imaging performance inspection through one inspection device.

In addition, since the optical characteristic inspection and the mask imaging performance inspection for the pellicle and the mask may be performed without an optical system having a structure combined with a high-power light source, the time and costs required for the inspection may be minimized.

In addition, since an environment such as an actual exposure machine (e.g., an oblique incidence environment of 6°, a pellicle twice transmission environment), reflectivity measurement for the pellicle and the mask may be easily performed.

In addition, since an amount of EUV light used for the optical characteristic inspection may be maintained constant through continuous monitoring of the amount of light, the accuracy of the optical characteristic inspection for the pellicle and the mask may be improved.

In addition, since 0th-order diffraction light of EUV light diffracted from the mask may be controlled to pass through a central portion of an objective lens (e.g., an FZP lens), the accuracy of the mask imaging performance inspection result may be improved.

### DESCRIPTION OF DRAWINGS

FIG. 1 is a view for explaining a comprehensive inspection device for an EUV exposure process according to an embodiment of the present invention.

FIG. 2 is a view for explaining a light generation unit of the comprehensive inspection device for an EUV exposure process according to the embodiment of the present invention.

FIG. 3 is a view for explaining a splitter and an optical characteristic evaluation unit of the comprehensive inspection device for an EUV exposure process according to the embodiment of the present invention.

FIG. 4 is a view for explaining first EUV light and second EUV light that are split through the splitter of the comprehensive inspection device for an EUV exposure process according to the embodiment of the present invention.

FIG. 5 is a view for explaining a mask and a pellicle that are disposed on a stage of the optical characteristic evaluation unit of the comprehensive inspection device for an EUV exposure process according to the embodiment of the present invention.

FIG. 6 is a view for explaining a process of detecting transmittance of the pellicle through the optical characteristic evaluation unit of the comprehensive inspection device for an EUV exposure process according to the embodiment of the present invention.

FIG. 7 is a view for explaining a process of detecting reflectance of the pellicle through the optical characteristic evaluation unit of the comprehensive inspection device for an EUV exposure process according to the embodiment of the present invention.

FIG. 8 is a view for explaining a process of detecting reflectance of a third sample through the optical characteristic evaluation unit of the comprehensive inspection device for an EUV exposure process according to the embodiment of the present invention.

FIG. 9 is a view for explaining an imaging inspection unit of the comprehensive inspection device for an EUV exposure process according to the embodiment of the present invention.

FIG. 10 is a perspective view an objective lens tilting module of the comprehensive inspection device for an EUV exposure process according to the embodiment of the present invention.

FIG. 11 is a view for explaining a coupling relationship between first and second plates and first to third driving modules of the objective lens tilting module according to the embodiment of the present invention.

FIGS. 12 and 13 are views for explaining the first to third driving modules of the objective lens tilting module according to the embodiment of the present invention.

FIGS. 14 and 15 are views for explaining a change in movement of the second plate through the first to third driving modules of the objective lens tilting module according to the embodiment of the present invention.

FIGS. 16 and 17 are views for explaining a lens holder of the objective lens tilting module according to the embodiment of the present application.

FIGS. 18 and 19 are views for explaining movement of the lens holder of the objective lens tilting module according to the embodiment of the present application.

FIG. 20 is a view for explaining a distance sensor of the objective lens tilting module according to an embodiment of the present invention.

### MODE FOR INVENTION

Hereinafter, preferred embodiments of the present invention will be described in detail with reference to the accompanying drawings. However, the present invention may be embodied in different forms and should not be construed as limited to the embodiments set forth herein. Rather, the embodiments introduced herein are provided so that the disclosed contents may be thorough and complete and the spirit of the present invention may be sufficiently conveyed to those skilled in the art.

In the present specification, it will be understood that when an element is referred to as being “on” another element, it may be formed directly on the other element or intervening elements may be present. In the drawings, the thicknesses of layers and regions are exaggerated for clarity.

In addition, it will be also understood that although the terms first, second, third, etc. may be used herein to describe various elements, these elements should not be limited by these terms. These terms are only used to distinguish one element from another element. Thus, a first element in some embodiments may be termed a second element in other embodiments without departing from the teachings of the present invention. Embodiments explained and illustrated herein include their complementary counterparts. As used herein, the term “and/or” includes any and all combinations of one or more of the associated listed elements.

The singular expression also includes the plural meaning as long as it does not differently mean in the context. In addition, the terms “comprise”, “have” etc., of the description are used to indicate that there are features, numbers, steps, elements, or combination thereof, and they should not exclude the possibilities of combination or addition of one or more features, numbers, operations, elements, or a combination thereof. Furthermore, it will be understood that when an element is referred to as being “connected” or “coupled” to another element, it may be directly connected or coupled to the other element or intervening elements may be present.

In addition, when detailed descriptions of related known functions or constitutions are considered to unnecessarily cloud the gist of the present invention in describing the present invention below, the detailed descriptions will not be included.

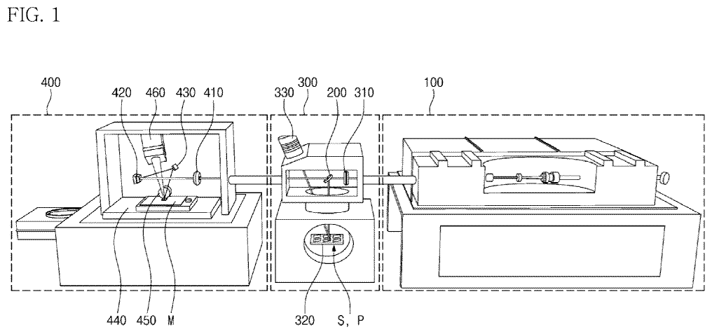

FIG. 1 is a view for explaining a comprehensive inspection device for an EUV exposure process according to an embodiment of the present invention.

Referring to FIG. 1, the comprehensive inspection device for an EUV exposure process according to the embodiment of the present invention may include a light generation unit 100, a splitter 200, an optical characteristic evaluation unit 300, and an imaging inspection unit 400. Hereinafter, the respective components will be described.

### Light Generation Unit 100

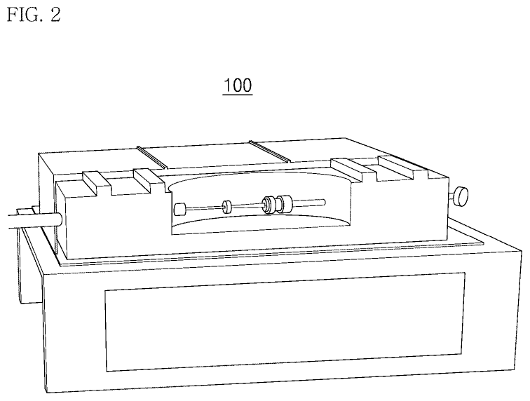

FIG. 2 is a view for explaining a light generation unit of the comprehensive inspection device for an EUV exposure process according to the embodiment of the present invention.

Referring to FIG. 2, the light generation unit 100 may generate coherent extreme ultra violet (EUV) light having a wavelength of 13.5 nm. The EUV light generated by the light generation unit 100 may be provided to the optical characteristic evaluation unit 300 to be described later. Hereinafter, the splitter 200, the optical characteristic evaluation unit 300, and the imaging inspection unit 400 will be described in detail.

### Splitter 200 And Optical Characteristic Evaluation Unit 300

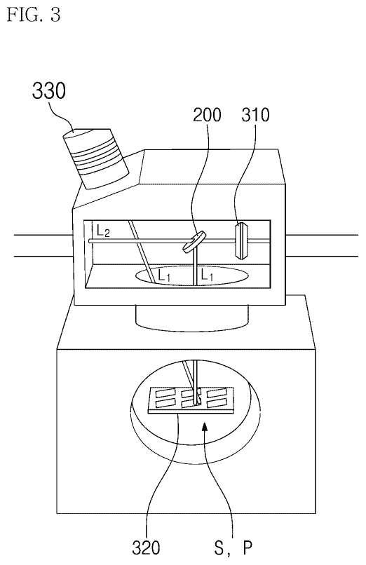

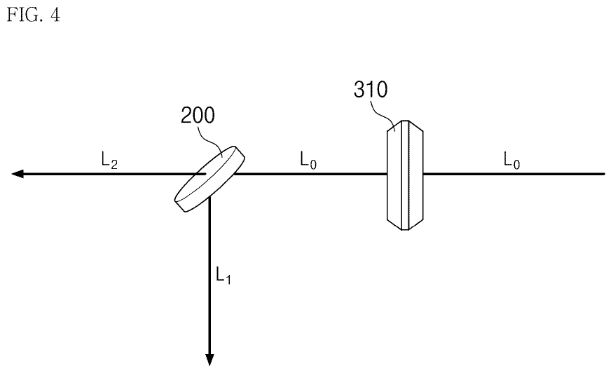

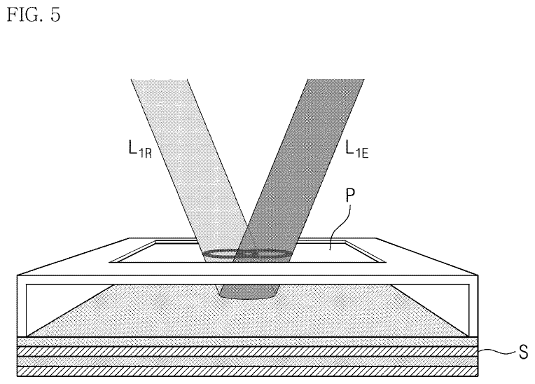

FIG. 2 is a view for explaining a light generation unit of the comprehensive inspection device for an EUV exposure process according to the embodiment of the present invention, FIG. 3 is a view for explaining a splitter and an optical characteristic evaluation unit of the comprehensive inspection device for an EUV exposure process according to the embodiment of the present invention, FIG. 4 is a view for explaining first EUV light and second EUV light that are split through the splitter of the comprehensive inspection device for an EUV exposure process according to the embodiment of the present invention, and FIG. 5 is a view for explaining a mask and a pellicle that are disposed on a stage of the optical characteristic evaluation unit of the comprehensive inspection device for an EUV exposure process according to the embodiment of the present invention.

Referring to FIGS. 3 and 4, the splitter 200 may be disposed in the optical characteristic evaluation unit 300. The splitter 200 may split the EUV light L₀ into first EUV light L₁ and second EUV light L₂ by receiving EUV light L₀ from the light generation unit 100. More specifically, the splitter 200 may reflect a part of the EUV light L₀ provided by the light generation unit 100 and transmit the remaining part thereof. The EUV light reflected by the splitter 200 may be defined as the first EUV light L₁. On the other hand, the EUV light transmitted through the splitter 200 may be defined as the second EUV light L₂. The first EUV light L₁ may be provided to the optical characteristic evaluation unit 300. On the other hand, the second EUV light L₂ may be provided to the imaging inspection unit 400 to be described later.

The optical characteristic evaluation unit 300 may include a first shutter 310, a first stage 320, a first detector 330, and a calculation unit (not shown). The first shutter 310 may control an amount of the EUV light L₀ provided by the light generation unit 100. The EUV light L₀, the amount of which is controlled through the first shutter 310, may be provided to the splitter 200. As described above, the splitter 200 may split the EUV light L₀ into the first EUV light L₁ and the second EUV light L₂.

The first EUV light L₁ split by the splitter 200 may be provided to the first stage 320. An object S and a pellicle P may be disposed on first stage 320. More specifically, as shown in FIG. 5, the pellicle P may be spaced apart from the object S to face the object S. According to one embodiment, the first stage 320 move in various directions.

As shown in FIG. 5, the first EUV light L₁ split by the splitter 200 may be provided to the object S after being transmitted through the pellicle P. The object S may reflect the first EUV light L₁. The first EUV light L₁ reflected from the object S may be re-transmitted through the pellicle P. According to one embodiment, the first EUV light L₁ before being reflected by the object S may be defined as first transmitted EUV light L_{1E}. On the other hand, the first EUV light L₁ reflected through the object S may be defined as first reflected EUV light L_{1R}.

The first detector 330 may measure an intensity of the first EUV light L₁ reflected from the object S, that is, an intensity of the first reflected EUV light L_{1R}. The calculation unit (not shown) may detect reflectance and transmittance of the pellicle P and reflectance of the object S through the intensity of the first reflected EUV light L_{1R} measured by the first detector 330.

According to one embodiment, the object S may include first to third samples S₁, S₂, and S₃. For example, the first sample S₁ may include a multilayer thin film mirror constituting an EUV mask. That is, the first sample S₁ may be a Mo/Si multilayer thin film mirror in which molybdenum (Mo) and silicon (Si) are sequentially and repeatedly stacked. On the other hand, the second sample S₂ may include a material for absorbing EUV. On the other hand, the third sample S₃ may include a material used in an EUV process.

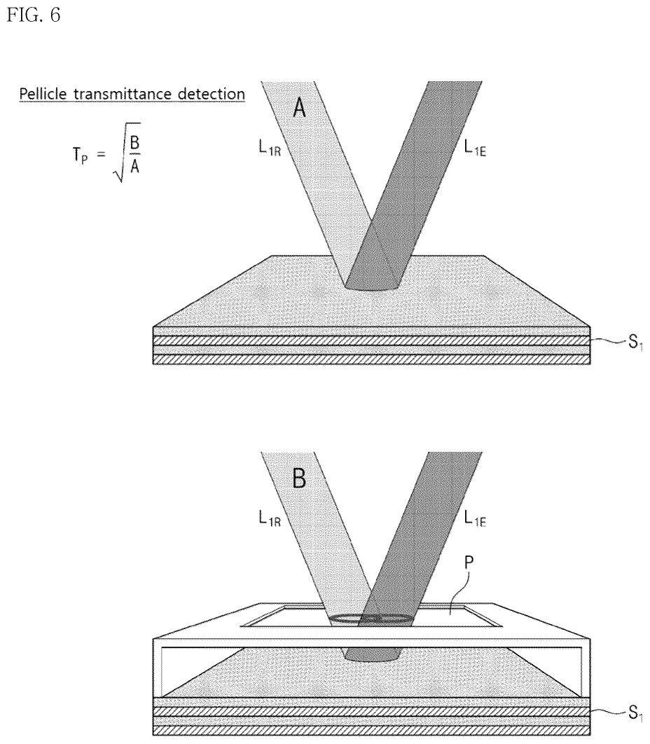

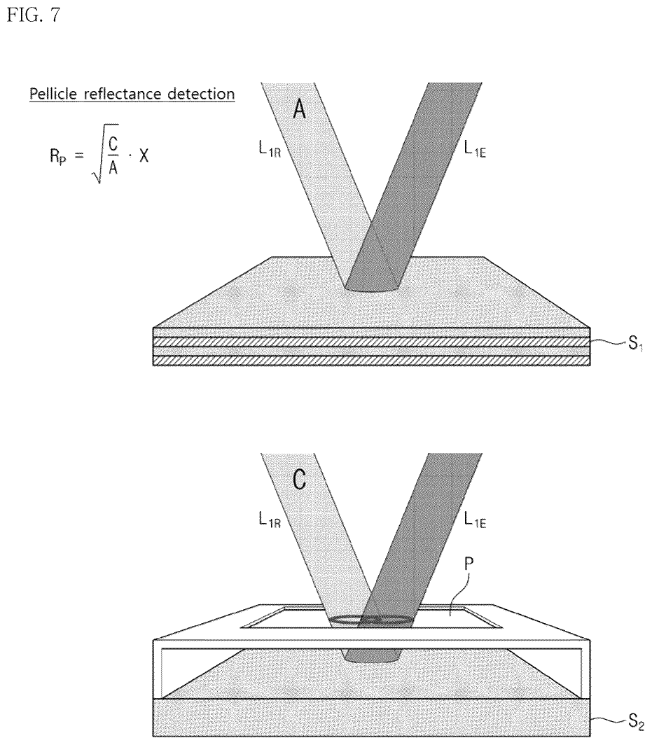

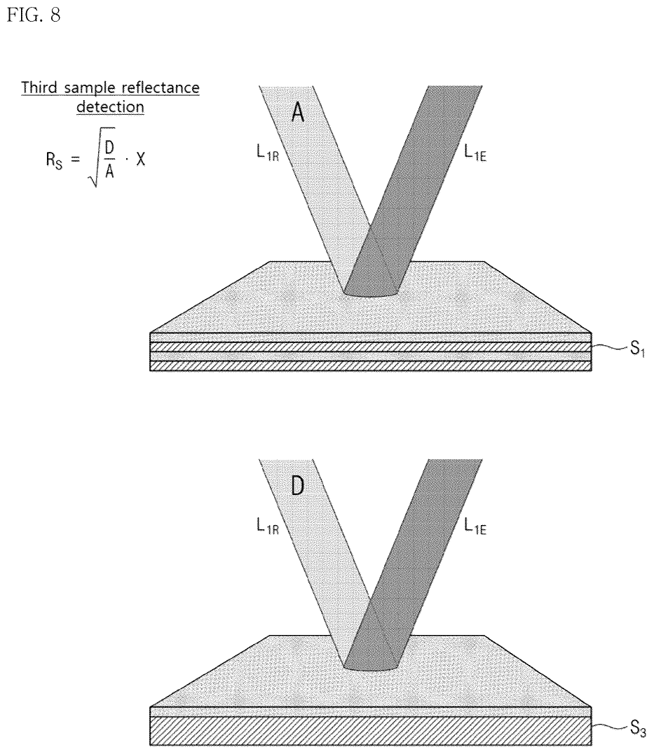

FIG. 6 is a view for explaining a process of detecting transmittance of the pellicle through the optical characteristic evaluation unit of the comprehensive inspection device for an EUV exposure process according to the embodiment of the present invention. FIG. 7 is a view for explaining a process of detecting reflectance of the pellicle through the optical characteristic evaluation unit of the comprehensive inspection device for an EUV exposure process according to the embodiment of the present invention, and FIG. 8 is a view for explaining a process of detecting reflectance of a third sample through the optical characteristic evaluation unit of the comprehensive inspection device for an EUV exposure process according to the embodiment of the present invention.

Referring to FIG. 6, the first detector 330 may measure an intensity of the first EUV light L_{1R}, which has been transmitted through the pellicle P, reflected from the first sample S₁ and re-transmitted through the pellicle P, and an intensity of the first EUV light L_{1R}, which has been directly reflected from the first sample S₁ without the pellicle P. According to one embodiment, the intensity of the first EUV light L_{1R}, which has been directly reflected from the first sample S₁ without the pellicle P, may be defined as A. On the other hand, the intensity of the first EUV light L_{1R}, which has been transmitted through the pellicle P, reflected from the first sample S₁ and re-transmitted through the pellicle P, may be defined as B.

The calculation unit may detect the transmittance of the pellicle P through A value and B value measured through the first detector 330. Specifically, the calculation unit may detect the transmittance of the pellicle P through the following <Equation 1>.

$${T}_{P} = \sqrt{\frac{B}{A}} \qquad 〈 Equation 1 〉$$

(T_{P}: Transmittance of pellicle, A: Intensity of the EUV light directly which has been reflected from the first sample without the pellicle, B: Intensity of the EUV light which has been transmitted through the pellicle, reflected from the first sample, and re-transmitted through the pellicle)

Referring to FIG. 7, the first detector 330 may measure an intensity of the first EUV light L_{1R}, which has been transmitted through the pellicle P, reflected from the second sample S₂, and re-transmitted through the pellicle P, and an intensity of the first EUV light L_{1R}, which has been directly reflected from the first sample S₁ without the pellicle P. According to one embodiment, the intensity of the first EUV light L_{1R}, which has been transmitted through the pellicle P, reflected from the second sample S₂, and re-transmitted through the pellicle P, may be defined as C.

The calculation unit may detect the reflectance of the pellicle P through A value and C value measured through the first detector 330. In addition, the reflectance of the first sample S₁ may be used in detecting the reflectance of the pellicle P. According to one embodiment, the reflectance of the first sample S₁ may be defined as X. For example, the X value may be 63%. Specifically, the calculation unit may detect the reflectance of the pellicle P through the following <Equation 2>.

$${R}_{P} = \sqrt{\frac{C}{A}} \cdot X \qquad 〈 Equation 2 〉$$

(R_{P}: Reflectance of pellicle, A: Intensity of the EUV light which has been directly reflected from the first sample without the pellicle, C: Intensity of the EUV light which has been transmitted through the pellicle, reflected from the second sample, and re-transmitted through the pellicle, X: Reflectance of the first sample)

Referring to FIG. 8, the first detector 330 may measure an intensity of the first EUV light L_{1R}, which has been directly reflected from the first sample S₁ without the pellicle P, and an intensity of the first EUV light L_{1R}, which has been directly reflected from the third sample S₃ without the pellicle P. According to one embodiment, the intensity of the first EUV light L_{1R}, which has been directly reflected from the third sample S₃ without the pellicle P, may be defined as D.

The calculation unit may detect reflectance of the third sample S₃ through A value and D value measured through the first detector 330. In addition, the reflectance of the first sample S₁ may be used in detecting the reflectance of the third sample S₃. According to one embodiment, the reflectance of the first sample S₁ may be defined as X. For example, the X value may be 63%. Specifically, the calculation unit may detect the reflectance of the third sample S₃ through the following <Equation 3>.

$${R}_{S} = \sqrt{\frac{D}{A}} \cdot X \qquad 〈 Equation 3 〉$$

(R_{S}: Reflectance of third sample. A: Intensity of the EUV light which has been directly reflected from the first sample without the pellicle, D: Intensity of the EUV light which has been directly reflected from the third sample without the pellicle, X: Reflectance of the first sample)

As described above, the third sample S₃ may include a material used in the EUV process. For example, the third sample S₃ may be a mask used in the EUV process. Accordingly, the optical characteristic evaluation unit 300 may detect reflectance of the mask used in the EUV process through <Equation 3>. As a result, the optical characteristic evaluation unit 300 may detect the reflectance and the transmittance of the pellicle P used in the EUV process, and the reflectance of the mask used in the EUV process.

### Imaging Inspection Unit 400

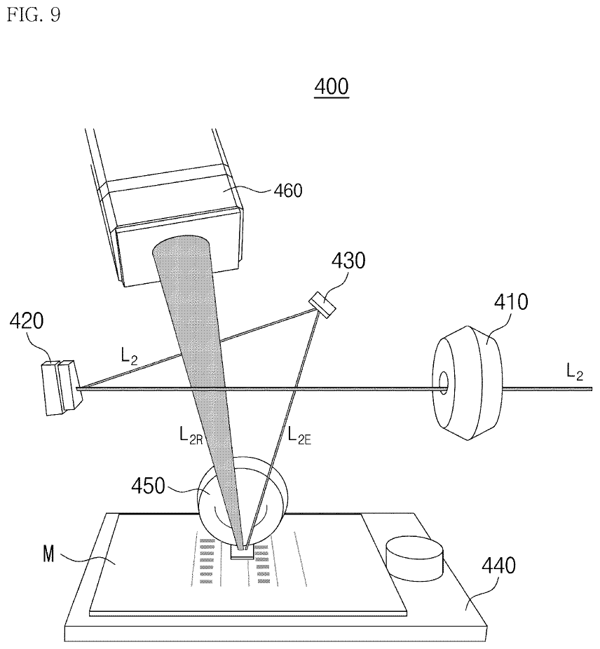

FIG. 9 is a view for explaining an imaging inspection unit of the comprehensive inspection device for an EUV exposure process according to the embodiment of the present invention.

Referring to FIG. 9, the imaging inspection unit 400 may include a second shutter 410, a first mirror 420, a second mirror 430, a second stage 440, an objective lens tilting module 450, and a second detector 460.

The second shutter 410 may control an amount of the second EUV light L₂ provided by the splitter 200. The second EUV light L₂, the amount of which is controlled through the second shutter 410, may be provided to the first mirror 420. The first mirror 420 may focus the second EUV light L₂. For example, the first mirror 420 may include a concave multilayer thin film mirror. The second EUV light L₂, the amount of which is focused through the first mirror 420, may be provided to the second mirror 430. The second mirror 430 may change a path of the second light L₂ such that the focused second EUV light L₂ is irradiated to an objective lens to be described later. For example, the second mirror 430 may include a planar multilayer thin film mirror. The second mirror 430 may change the path of the second light L₂ such that the second EUV light L₂ has an incident angle of 6° with respect to the objective lens to be described later.

A mask M used in the EUV process may be disposed on the second stage 440. The objective lens may be disposed on the objective lens tilting module 450. For example, the objective lens may include a Fresnel zone plate (FZP) lens.

As described above, since the imaging inspection unit 400 may perform the imaging inspection of the mask through the FZP lens, an inspection process may be simplified compared to a conventional mask imaging performance inspection device that inspects the mask imaging performance using the coherence diffraction imaging (CDI). Specifically, the conventional inspection device that inspects the mask imaging performance using CDI requires a complicated mathematical operation for phase restoration. However, when the FZP lens is used, a mask aerial image may be directly obtained without a complicated mathematical operation for phase restoration, and thus the inspection process may be simplified.

According to one embodiment, the objective lens tilting module 450 may be disposed on the second stage 440. Accordingly, the second EUV light L₂ provided through the first mirror 430 may be provided to the mask M while passing through the objective lens. The mask M may reflect and diffract the second EUV light L₂. The second EUV light L₂ reflected and diffracted by the mask M may be provided again to the objective lens. The objective lens may focus the second EUV light L₂ reflected and diffracted by the mask M. The second EUV light L₂ focused through the objective lens may be provided to the second detector 460. According to one embodiment, the second EUV light L₂ before being reflected and diffracted by the mask M may be defined as second transmitted EUV light L_{2E}. On the other hand, the second EUV light L₂ reflected and diffracted by the mask M may be defined as second reflected EUV light L_{2R}.

The second detector 460 may collect the second EUV light L₂ focused through the objective lens to form an aerial image. The imaging inspection unit 400 may inspect imaging performance of the mask M through the aerial image obtained through the second detector 460.

According to one embodiment, the optical characteristic inspection device for an EUV exposure process may continuously monitor the intensities of the first EUV light L₁ and the second EUV light L₂ through the first detector 330 and the second detector 460, respectively. Based on the intensities of the first EUV light L₁ and the second EUV light L₂ monitored through the first detector 330 and the second detector 460, respectively, the light generation unit 100 may be controlled such that the intensity of the first EUV light L₁, which has been detected through the first detector 330, and the intensity of the second EUV light L₂, which has been detected by the second detector 460, are maintained constant.

In addition, the optical characteristic inspection device for an EUV exposure process may synchronize operations of the first shutter 310 and the second shutter 410. That is, the first shutter 310 and the second shutter 410 may be simultaneously controlled. Accordingly, it is possible to suppress a problem in which the intensity of the first EUV light L₁ and the intensity of the second EUV light L₂, which have been detected by the first detector 330 and the second detector 460, respectively, are changed by the first shutter 310 and the second shutter 410. As a result, through the synchronization of the first shutter 310 and the second shutter 410, the intensity of the first EUV light L₁, which has been detected through the first detector 330, and the intensity of the second EUV light L₂, which has been detected through the second detector 460, may be maintained constant.

As described above, in order to obtain an aerial image of the mask M through the objective lens (e.g., the FZP lens), a precise alignment needs to be performed between the objective lens and the second EUV light L_{2R} diffracted from the mask M. More specifically, the second EUV light L_{2R} diffracted from the mask M needs to have an inclination of 0.03° or greater and a depth of focus of 0.36 μm, and 0th-order diffraction light needs to pass through the center of the objective lens. The imaging inspection unit 400 may precisely align the objective lens with the second EUV light L_{2R} diffracted from the mask M through the objective lens tilting module 450. Hereinafter, the objective lens tilting module 450 will be described in detail.

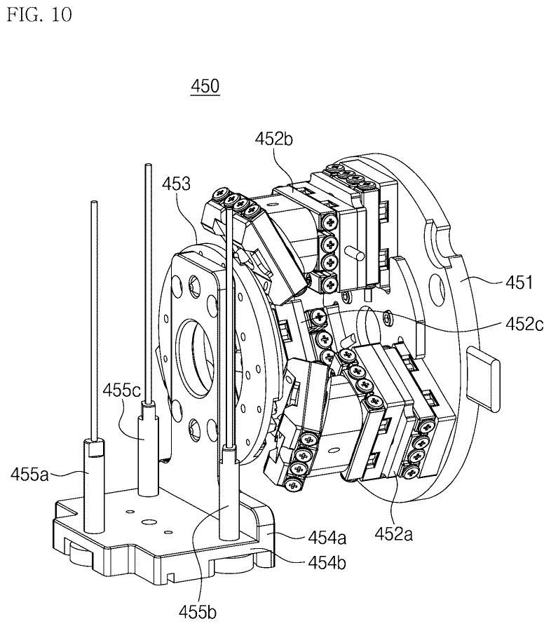

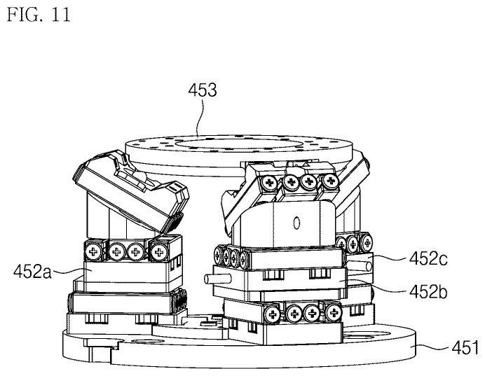

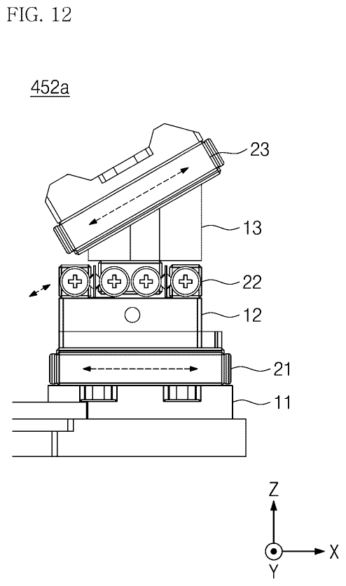

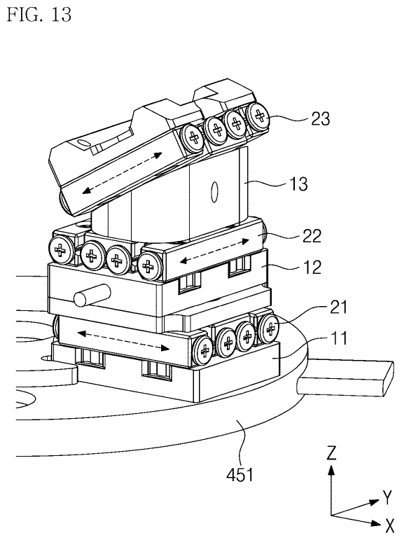

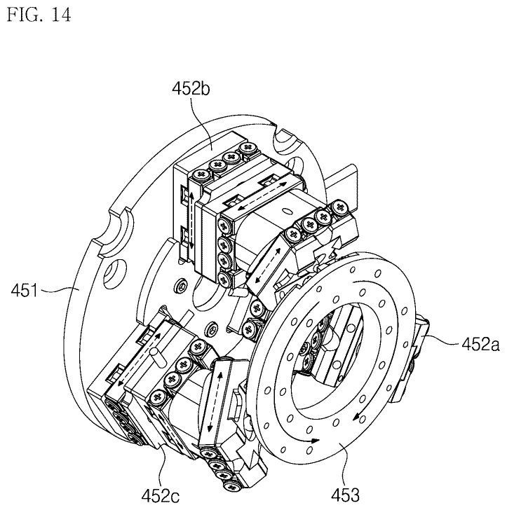

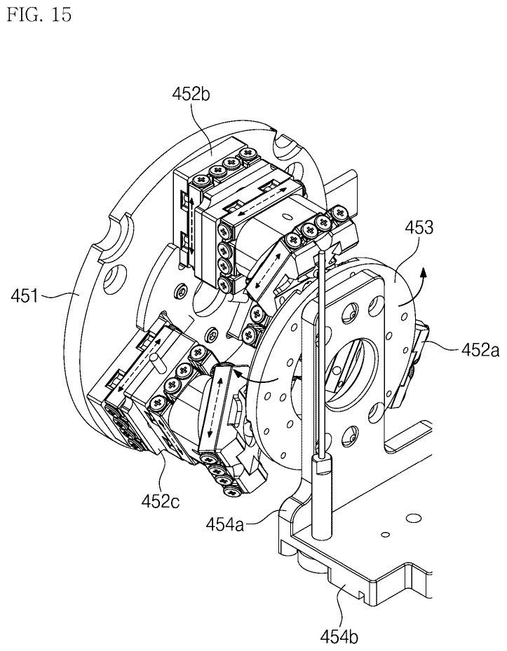

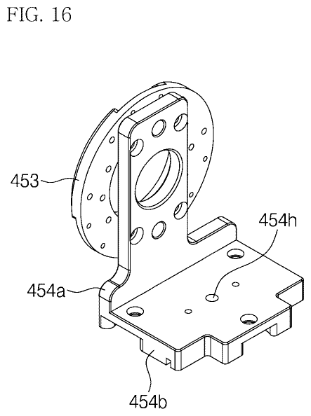

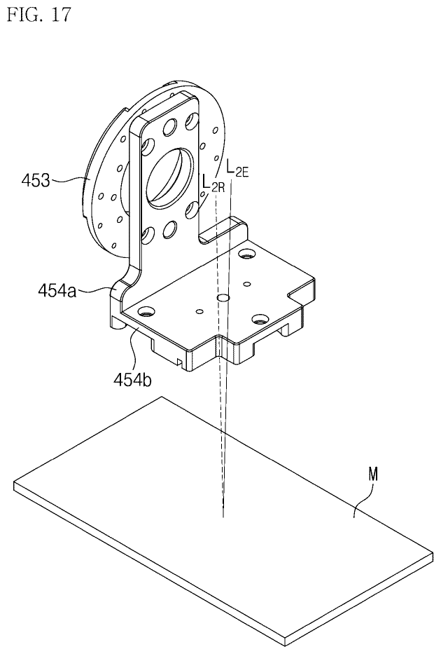

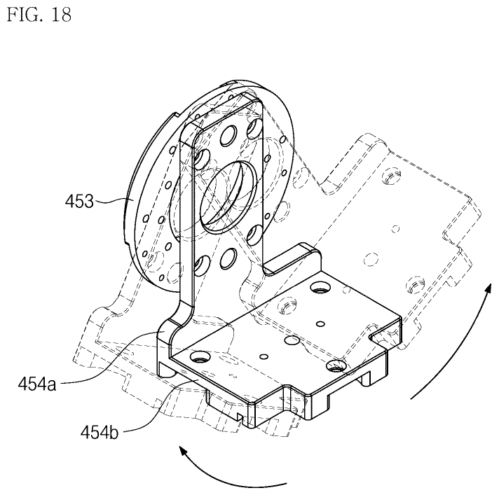

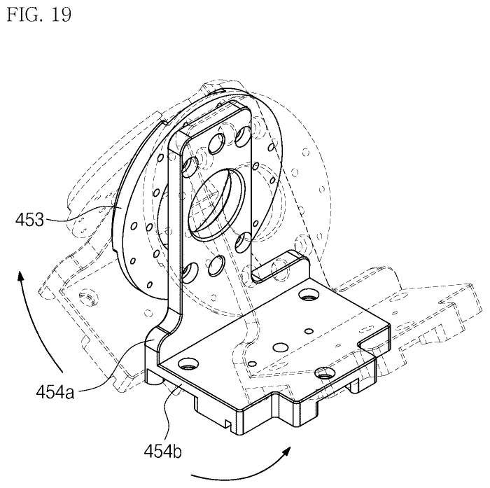

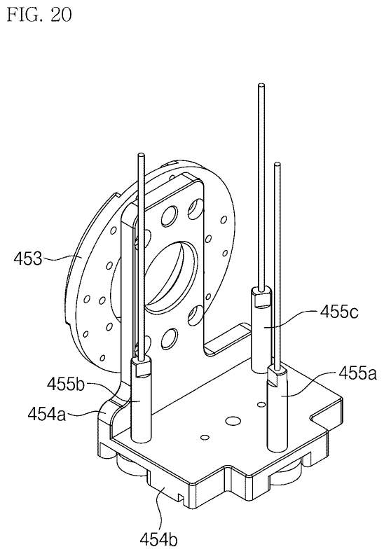

FIG. 10 is a perspective view an objective lens tilting module of the comprehensive inspection device for an EUV exposure process according to the embodiment of the present invention, FIG. 11 is a view for explaining a coupling relationship between first and second plates and first to third driving modules of the objective lens tilting module according to the embodiment of the present invention, FIGS. 12 and 13 are views for explaining the first to third driving modules of the objective lens tilting module according to the embodiment of the present invention, FIGS. 14 and 15 are views for explaining a change in movement of the second plate through the first to third driving modules of the objective lens tilting module according to the embodiment of the present invention, FIGS. 16 and 17 are views for explaining a lens holder of the objective lens tilting module according to the embodiment of the present application, FIGS. 18 and 19 are views for explaining movement of the lens holder of the objective lens tilting module according to the embodiment of the present application, and FIG. 20 is a view for explaining a distance sensor of the objective lens tilting module according to an embodiment of the present invention.

Referring to FIG. 10, the objective lens tilting module 450 may include a first plate 451, first to third driving modules 452a, 452b, and 452c, a second plate 453, lens holders 454a and 454b, first to third distance sensors 455a, 455b, and 455c, and a control unit (not shown).

Referring to FIGS. 10 and 11, the first plate 451 may be used as a support for supporting the first to third driving modules 452a, 452b, and 452c. According to one embodiment, the first plate 451 may have a circle plate shape.

The first to third driving modules 452a, 452b, and 452c may be disposed on the first plate 451. According to one embodiment, one end of each of the first to third driving modules 452a, 452b, and 452c may be coupled to the first plate 451. According to one embodiment, the first to third driving modules 452a, 452b, and 452c may be spaced apart from each other along a circumferential direction of the first plate 451.

Referring to FIGS. 12 and 13, the first driving module 452a may include a lower supporter 11, a middle supporter 12, an upper supporter 13, a lower slide 21, a middle slide 22, and an upper slide 33. The lower supporter 11, the lower slide 21, the middle supporter 12, the middle slide 22, the upper supporter 13, and the upper slide 33 may be sequentially stacked.

The lower supporter 11 may be disposed at the lowermost end of the first driving module 452a and coupled to the first plate 451. The lower supporter 11 may be used as a support for supporting the lower slide 21. According to one embodiment, a lower surface of the lower supporter 11 may be coupled to the first plate 451, and an upper surface of the lower supporter 11 may be coupled to the lower slide 12. According to one embodiment, the lower supporter 11 may be disposed to be parallel to an upper surface of the first plate 451. That is, both the upper and lower surfaces of the lower support 11 may be parallel to the upper surface of the first plate 451.

The lower slide 21 may be disposed on the lower supporter 11. According to one embodiment, a lower surface of the lower slide 21 may be coupled to the lower supporter 11, and an upper surface of the lower slide 21 may be coupled to the middle supporter 12. According to one embodiment, the lower slide 21 may be disposed to be parallel to the upper surface of the first plate 451. That is, both the upper and lower surfaces of the lower slide 21 may be parallel to the upper surface of the first plate 451. The lower slide 21 may slidably move between the lower supporter 11 and the middle supporter 12. Specifically, the lower slide 21 may linearly reciprocate in a first direction parallel to the upper surface of the first plate 451. For example, the first direction may be an X-axis direction shown in FIGS. 12 and 13.

The middle supporter 12 may be disposed on the lower slide 21. According to one embodiment, a lower surface of the middle supporter 12 may be coupled to the lower slide 21, and an upper surface of the middle supporter 12 may be coupled to the middle slide 22. The middle supporter 12 may be used as a support for supporting the middle slide 22. According to one embodiment, the middle supporter 12 may be disposed to be parallel to the upper surface of the first plate 451. That is, both the upper and lower surfaces of the middle supporter 12 may be parallel to the upper surface of the first plate 451.

The middle slide 22 may be disposed on the middle supporter 12. According to one embodiment, a lower surface of the middle slide 22 may be coupled to the middle supporter 12, and an upper surface of the middle slide 22 may be coupled to an upper surface of the upper supporter 13. According to one embodiment, the middle slide 22 may be disposed to be parallel to the upper surface of the first plate 451. That is, both the upper and lower surfaces of the middle slide 22 may be parallel to the upper surface of the first plate 451. The middle slide 22 may slidably move between the middle supporter 12 and the upper supporter 13. Specifically, the middle slide 22 may linearly reciprocate in a second direction parallel to the upper surface of the first plate 451 and perpendicular to the first direction (X-axis direction). For example, the second direction may be a Y-axis direction shown in FIGS. 12 and 13.

The upper supporter 13 may be disposed on the middle slide 22. According to one embodiment, a lower surface of the upper supporter 13 may be coupled to the middle slide 22, and the upper surface of the upper supporter 13 may be coupled to the upper slide 23. According to one embodiment, the lower surface and the upper surface of the upper supporter 13 may not be parallel. Specifically, the lower surface of the upper supporter 13 may be parallel to the upper surface of the first plate 451. On the other hand, the upper surface of the upper supporter 13 may have an inclination with respect to a third direction perpendicular to the first direction (X-axis direction) and the second direction (Y-axis direction). For example, the third direction may be a Z-axis direction shown in FIGS. 12 and 13. The upper supporter 13 may be used as a support for supporting the upper slide 23.

The upper slide 23 may be disposed on the upper supporter 13. According to one embodiment, a lower surface of the upper slide 23 may be coupled to the upper supporter 13, and an upper surface of the upper slide 23 may be coupled to an upper surface of the upper supporter 453.

The upper slide 23 may have an inclination together with the upper surface of the upper supporter 13. Specifically, one side of the upper slide 23 may be disposed relatively close to the first plate 451, and the other side of the upper slide 23 may be disposed relatively far from the first plate 451. According to one embodiment, one side of the upper slide 23 may be defined as a place adjacent to the central portion of the first plate 23. On the other hand, the other side of the upper slide 23 may be defined as a place adjacent to an outer portion of the first plate 23. That is, the upper slide 23 may have an inclination that increases from the central portion toward the outer portion of the first plate 451.

The upper slide 23 may slidably move between the upper supporter 13 and the second plate 453. According to one embodiment, the upper slide 23 may linearly reciprocate along the inclination formed on the upper slide 23. Specifically, the upper slide 23 may linearly reciprocate in a fourth direction inclined with respect to the third direction (Z-axis direction). For example, the fourth direction may be a direction between a Z-axis and a Y-axis or a direction between a Z-axis and an X-axis shown in FIGS. 12 and 13.

The second driving module 452b and the third driving module 452c may have the same configuration as the first driving module 452a. Accordingly, the detailed description thereof will be omitted.

Referring to FIGS. 14 and 15, the other end of each of the first to third driving modules 452a, 452b, and 452c may be coupled to the second plate 453. That is, the one end of each of the first to third driving modules 452a, 452b, and 452c may be coupled to the first plate 451, and the other end thereof may be coupled to the second plate 453.

According to one embodiment, the second plate 453 may have a circle plate shape. A diameter of the second plate 453 may be smaller than a diameter of the first plate 451.

When the lower slide, the middle slide, and the upper slide of the first to third driving modules 452a, 452b, and 452c linearly reciprocate, the movement of the second plate 453 may be changed by the first to third driving modules 452a, 452b, and 452c. Specifically, as shown in FIG. 14, the second plate 453 may be rotated clockwise or counterclockwise along the circumferential direction of the second plate 453. In addition, as shown in FIG. 15, the inclination of the second plate 453 may be changed.

Referring to FIGS. 16 to 19, the lens holders 454a and 454b may be coupled to the second plate 453. According to one embodiment, the lens holders 454a and 454b may include a first lens holder 454a and a second lens holder 454b. The first lens holder 454a may be coupled to the second plate 453. The second lens holder 454b may be coupled to the first lens holder 454a. The coupled first lens holder 454a and the second lens holder 454b may have a ‘L’ shape.

The objective lens may be disposed inside the second lens holder 454b. Specifically, the objective lens may be disposed inside the second lens holder 454b such that the objective lens is parallel to the mask M disposed on the second stage 440.

According to one embodiment, a light inflow hole 454h may be formed in the second lens holder 454b. The second EUV light L_{2E} provided through the second mirror 430 may be provided to the objective lens through the light inflow hole 454h. The second EUV light L_{2E} provided to the objective lens may be provided to the mask M after being transmitted through the objective lens. The second EUV light L_{2E} provided to the mask M may be reflected and diffracted by the mask M. The second EUV light L_{2R} reflected and diffracted by the mask M may be re-transmitted through the objective lens, and escape from the second lens holder 454b through the light inflow hole 454h. The second EUV light L_{2R} escaping from the second lens holder 454b may be provided to the second detector 460.

As described above, as the lens holders 454a and 454b are coupled to the second plate 453, the lens holders 454a and 454b may also move by the movement of the second plate 454. Specifically, as shown in FIGS. 18 and 19, the lens holders 454a and 454b may be rotated along the circumferential direction of the second plate 453 or may move back and forth due to a change in inclination. Therefore, the objective lens disposed inside the second lens holder 454b may be changed in position.

The first to third distance sensors 455a, 455b, and 455c may be disposed on the second lens holder 454b. Specifically, the first to third distance sensors 455a, 455b, and 455c may be spaced apart from each other to surround the objective lens. The first to third distance sensors 455a, 455b 455c may sense a distance between the objective lens and the mask M. According to one embodiment, the first to third distance sensors 455a, 455b 455c may sense the distance between the objective lens and the mask M using electric and magnetic fields.

The control unit (not shown) may control the first to third driving modules 452a, 452b, and 452c based on the distance between the objective lens and the mask M measured through the first to third distance sensors 455a, 455b, and 455c. Specifically, the control unit may control the first to third driving modules 452a, 452b, and 452c such that the second EUV light L_{2R} diffracted from the mask M has an inclination of 0.03° or greater and a depth of focus of 0.36 μm and the 0th-order diffraction light passes through the central portion of the objective lens. Accordingly, a precise alignment may be performed between the second EUV light L_{2R} diffracted from the mask M and the objective lens.

Unlike the above description, when the 0th-order diffraction light does not pass through the central portion of the objective lens (e.g., the FZP lens), a difference in intensity between +1st-order diffraction light and −1st-order diffraction light may be caused, and an amount of diffraction light irradiated to the objective lens may be reduced overall. Accordingly, an error may occur in the result of the inspection of the image performance of the mask M.

However, as described above, since the objective lens tilting module 450 may be controlled such that the 0th-order diffraction light of the second EUV light L_{2R}, which is diffracted from the mask M, passes through the central portion of the objective lens, the accuracy of the inspection result of the imaging performance of the mask M may be improved.

As a result, the comprehensive inspection device for an EUV exposure process according to the embodiment of the present invention may perform both optical characteristic inspection for a pellicle and a mask for the EUV exposure process and mask imaging performance inspection through one inspection device.

In addition, since the optical characteristic inspection and the mask imaging performance inspection for the pellicle and the mask may be performed without an optical system having a structure combined with a high-power light source, the time and costs required for the inspection may be minimized.

In addition, since an environment such as an actual exposure machine (e.g., an oblique incidence environment of 6°, a pellicle twice transmission environment), reflectivity measurement for the pellicle and the mask may be easily performed.

In addition, since an amount of EUV light used for the optical characteristic inspection may be maintained constant through continuous monitoring of the amount of light, the accuracy of the optical characteristic inspection for the pellicle and the mask may be improved.

In addition, since zero-order diffraction light of EUV light diffracted from the mask may be controlled to pass through a central portion of an objective lens (e.g., an FZP lens), the accuracy of the mask imaging performance inspection result may be improved.

While the present: invention has been described in connection with the embodiments, it is not to be limited thereto but will be defined by the appended claims. In addition, it is to be understood that those skilled in the art may substitute, change, or modify the embodiments in various forms without departing from the scope and spirit of the present invention.

### INDUSTRIAL APPLICABILITY

The comprehensive inspection device for an EUV exposure process according to the embodiment of the present invention may be applied to the semiconductor industry.

The invention claimed is:

1. A comprehensive inspection device for an EUV exposure process, the comprehensive inspection device comprising:
a light generation unit configured to generate EUV light;
a splitter configured to split the EUV light into first EUV light and second EUV light by receiving the EUV light from the light generation unit;
an optical characteristic evaluation unit configured to detect reflectance and transmittance of the pellicle and reflectance of the object by measuring an intensity of the first EUV light, which has been transmitted through the pellicle, reflected from an object, and re-transmitted through the pellicle, and an intensity of the first EUV light, which has been directly reflected from the object without the pellicle; and
an imaging inspection unit configured to inspect imaging performance of a mask by focusing the second EUV light, which has been reflected and diffracted from the mask, through an objective lens, and collecting the focused second EUV light to obtain an aerial image.

2. The comprehensive inspection device of claim 1, wherein the object includes a first sample including a multilayer thin film mirror, and
the optical characteristic evaluation unit measures the transmittance of the pellicle by measuring an intensity of the first EUV light, which has been transmitted through the pellicle, reflected from the first sample, and re-transmitted through the pellicle, and an intensity of the first EUV light, which has been directly reflected from the first sample without the pellicle.

3. The comprehensive inspection device of claim 2, wherein the object further includes a second sample including a material for absorbing EUV, and
the optical characteristic evaluation unit detects the reflectance of the pellicle by measuring an intensity of the first EUV light, which has been transmitted through the pellicle, reflected from the second sample, and re-transmitted through the pellicle, and an intensity of the first EUV light, which has been directly reflected from the first sample without the pellicle.

4. The comprehensive inspection device of claim 2, wherein the object further includes a third sample including a material used in an EVU process, and
the optical characteristic evaluation unit detects reflectance of the third sample by measuring an intensity of the first EUV light, which has been directly reflected from the first sample without the pellicle, and an intensity of the first EUV light, which has been directly reflected from the third sample without the pellicle.

5. The comprehensive inspection device of claim 1, wherein the imaging inspection unit includes:
a distance sensor configured to sense a distance between the objective lens and the mask;
a control unit configured to confirm an inclination of the objective lens by using the distance measured through the distance sensor; and
a tilting module configured to control a position of the objective lens, and
the tilting module controls the position of the objective lens such that 0th-order diffraction light among diffraction light of the second EUV light, which has been diffracted from the mask, passes through a central portion of the objective lens.

6. The comprehensive inspection device of claim 5,
wherein the imaging inspection unit further includes
a first mirror configured to focus the second EUV light provided by the splitter, and a second mirror configured to change a path of the second EUV light such that the second EUV light focused through the first mirror is irradiated to the objective lens.

7. The comprehensive inspection device of claim 1, wherein the splitter reflects a part of the EUV light provided by the light generation unit and transmits a remaining part of the EUV light, and
the EUV light reflected by the splitter is defined as the first EUV light, and the EUV light transmitted through the splitter is defined as the second EUV light.

8. An optical characteristic inspection device for an EUV exposure process, the optical characteristic inspection device comprising:
a light source configured to provide EUV light;
an object which includes a first sample including a multilayer thin film mirror, a second sample including a material for absorbing EUV, and a third sample including a material used in an EUV process, and irradiated with the EUV light provided by the light source;
a pellicle spaced apart from the object to face the object;
a detector configured to measure an intensity of the EUV light, which has been transmitted through the pellicle, reflected from the object, and re-transmitted through the pellicle, and an intensity of the EUV light, which has been directly reflected from the object without the pellicle; and
a calculation unit configured to detect reflectance and transmittance of the pellicle and reflectance of the object through the intensity of the EUV light detected through the detector.

9. The optical characteristic inspection device of claim 8, wherein the calculation unit detects the transmittance of the pellicle through the following <Equation 1>.
$${T}_{P} = \sqrt{\frac{B}{A}} \qquad 〈 Equation 1 〉$$
(T_{P}: Transmittance of pellicle, A: Intensity of the EUV light which has been directly reflected from the first sample without the pellicle, B: Intensity of the EUV light which has been transmitted through the pellicle, reflected from the first sample, and re-transmitted through the pellicle)

10. The optical characteristic inspection device of claim 8, wherein the calculation unit detects the reflectance of the pellicle through the following <Equation 2>.
$${R}_{P} = \sqrt{\frac{C}{A}} \cdot X \qquad 〈 Equation 2 〉$$
(R_{P}: Reflectance of pellicle, A: Intensity of the EUV light which has been directly reflected from the first sample without the pellicle, C: Intensity of the EUV light which has been transmitted through the pellicle, reflected from the second sample, and re-transmitted through the pellicle, X: Reflectance of the first sample)

11. The optical characteristic inspection device of claim 8, wherein the calculation unit detects the reflectance of the third sample through the following <Equation 3>.
$${R}_{S} = \sqrt{\frac{D}{A}} \cdot X \qquad 〈 Equation 3 〉$$
(R_{S}: Reflectance of third sample. A: Intensity of the EUV light which has been directly reflected from the first sample without the pellicle, D: Intensity of the EUV light which has been directly reflected from the third sample without the pellicle, X: Reflectance of the first sample)

12. An objective lens tilting device comprising:
first to third driving modules spaced apart from each other along a circumferential direction;
a first plate having a circle plate shape, which is coupled to one end of each of the first to third driving modules to support the first to third driving modules;
a second plate having a circle plate shape, which is coupled to the other end of each of the first to third driving modules so that movement thereof is changed by the first to third driving module; and
a lens holder coupled to the second plate so that movement thereof is changed by the second plate, and having an objected lens mounted thereon,
wherein the second plate and the lens holder is rotated along a circumferential direction of the second plate by the first to third driving modules, or is changed in inclination, and
a position of the objective lens mounted on the lens holder is changed due to the change in movement of the lens holder so that alignment of EUV light focused through the objective lens is controlled.

13. The objective lens tilting device of claim 12, wherein each of the first to third finger modules includes:
a lower slide configured to linearly reciprocate in a first direction parallel to an upper surface of the first plate;
a middle slide disposed on the lower slide, and configured to linearly reciprocate in a second direction parallel to the upper surface of the first plate and perpendicular to the first direction; and
an upper slide disposed on the middle slide, and configured to linearly reciprocate in a fourth direction inclined with respect to a third direction perpendicular to the first direction and the second direction.

14. The objective lens tilting device of claim 12, further comprising a distance sensor configured to sense a distance between the objective lens and a mask for reflecting the EUV light,
wherein an inclination of the objective lens is confirmed using the distance measured through the distance sensor, and the first to third driving modules are controlled to allow 0th-order diffraction light among diffraction light of the EUV light, which has been diffracted from the mask, to pass through a central portion of the objective lens.
